(19) United States
(12) Patent Application Publication
(10) Pub. No.: US 2025/0357362 A1
(43) Pub. Date: Nov. 20, 2025

(54) SEMICONDUCTOR APPARATUS AND POWER CONVERSION APPARATUS

(71) Applicant: Mitsubishi Electric Corporation, Tokyo (JP)

(72) Inventors: Yu ANDO, Tokyo (JP); Toshiya TADAKUMA, Tokyo (JP); Ikumi FUKUDA, Tokyo (JP)

(73) Assignee: Mitsubishi Electric Corporation, Tokyo (JP)

(21) Appl. No.: 19/041,019

(22) Filed: Jan. 30, 2025

(30) Foreign Application Priority Data
May 16, 2024 (JP) 2024-080113

(51) Int. Cl. H01L 23/552; H01L 23/31; H01L 23/495; H01L 25/18

(52) U.S. Cl. CPC H01L 23/552; H01L 23/49541; H01L 23/49575; H01L 25/18; H01L 23/3107

(57) ABSTRACT

A semiconductor apparatus includes: a semiconductor device; a control terminal; first and second main terminals respectively connected to first and second main electrodes of the semiconductor device; a sealing material; a capacitor module; a first busbar connected to a first electrode of the capacitor module, and connected to the first main terminal outside the sealing material; a second busbar connected to a second electrode, and connected to the second main terminal outside the sealing material; a control substrate disposed on an upper surface of the sealing material; and a shield plate disposed between the sealing material and the control substrate. The shield plate is extended to cover exposed portions of the first and second busbars not covered with a housing of the capacitor module, or is bent to cover a side surface of the control substrate near the exposed portions.

### BACKGROUND OF THE INVENTION

### Field

The present disclosure relates to a semiconductor apparatus and a power conversion apparatus.

### Background

WO 2014/064806 discloses a semiconductor apparatus in which a shield plate shielding against radiation noise is disposed on an upper surface electrode side of a semiconductor device, and a part of the upper surface electrode, a part of the shield plate, and the semiconductor device are sealed by a sealing material. The shield plate is formed integrally with the sealing material, which makes it possible to secure a heat dissipation path on an upper surface side of the semiconductor device in addition to a lower surface side. Furthermore, it is possible to suppress influence of radiation noise generated from the semiconductor device, on a control substrate fixed to be positioned above the shield plate.

The above-described method, however, has an issue that influence of radiation noise generated outside the sealing material sealing the semiconductor device, on the control substrate cannot be prevented.

### SUMMARY

To solve the above-described issue, the present disclosure is directed to a semiconductor apparatus that can prevent radiation noise generated outside the sealing material sealing the semiconductor device, from affecting the control substrate.

The features and advantages of the present disclosure may be summarized as follows.

According to an aspect of the present disclosure, a semiconductor apparatus comprises a semiconductor device including a control electrode, a first main electrode, and a second main electrode; a control terminal connected to the control electrode; first and second main terminals respectively connected to the first and second main electrodes; a sealing material configured to seal the semiconductor device, a part of the control terminal, and a part of the first and second main terminals; a capacitor module including a housing and first and second electrodes drawn out from the housing; a first busbar connected to the first electrode, and connected to the first main terminal outside the sealing material; a second busbar connected to the second electrode, and connected to the second main terminal outside the sealing material; a control substrate disposed to face an upper surface of the sealing material, and connected to the control terminal; and a shield plate disposed between the sealing material and the control substrate, and configured to shield against radiation, wherein the shield plate is extended to cover a part or all of exposed portions of the first and second busbars not covered with the housing, or is bent to cover a side surface of the control substrate near the exposed portions.

Other and further objects, features and advantages of the invention will appear more fully from the following description.

### BRIEF DESCRIPTION OF DRAWINGS

FIG. 1 is a perspective view illustrating a plurality of semiconductor modules mounted on a cooler according to a first embodiment of the present disclosure.

FIG. 2A is a top view illustrating one semiconductor module according to the first embodiment of the present disclosure.

FIG. 2B is a cross-sectional view taken along line A-A in FIG. 2A.

FIG. 3 is a circuit diagram of the semiconductor apparatus according to the first embodiment of the present disclosure.

FIG. 4 is a perspective view of the plurality of semiconductor modules and the shield plate provided thereon according to the first embodiment of the present disclosure.

FIG. 5 is a top view of FIG. 4.

FIG. 6 is a perspective view illustrating the semiconductor apparatus according to the first embodiment of the present disclosure.

FIG. 7 is a side view taken along line A-A′ in FIG. 6.

FIG. 8 illustrates a modification of the semiconductor apparatus according to the first embodiment of the present disclosure.

FIG. 9 illustrates another modification of the semiconductor apparatus according to the first embodiment of the present disclosure.

FIG. 10 is a side view illustrating the semiconductor apparatus according to a second embodiment of the present disclosure.

FIG. 11 is a side view illustrating the semiconductor apparatus according to a third embodiment of the present disclosure.

FIG. 12 is a block diagram illustrating a configuration of a power conversion system according to the fourth embodiment of the present disclosure.

### DESCRIPTION OF EMBODIMENTS

Some embodiments of the present disclosure are described with reference to drawings. The same or corresponding components are denoted by the same reference numerals, and repetitive description is omitted in some cases.

### First Embodiment

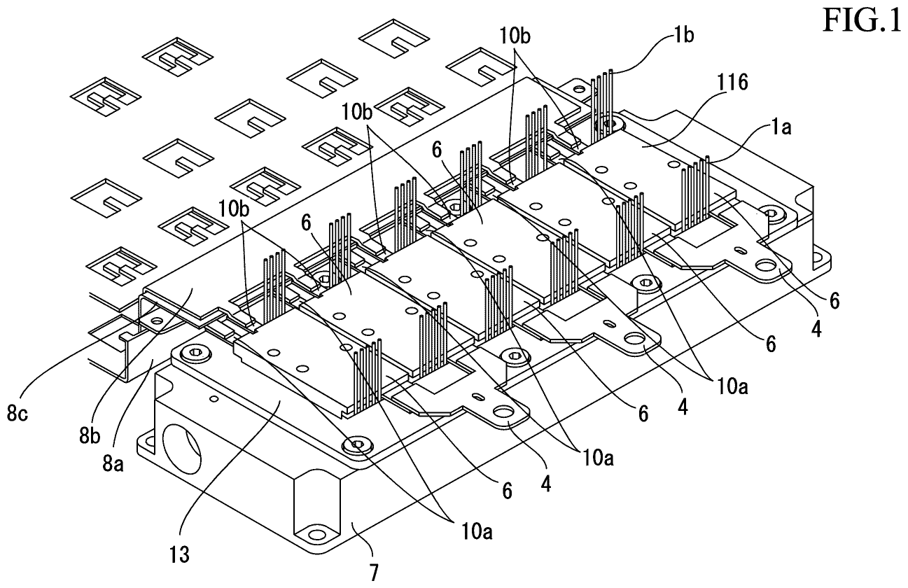

FIG. 1 is a perspective view illustrating a plurality of semiconductor modules 6 mounted on a cooler 7 according to a first embodiment of the present disclosure. The plurality of semiconductor modules 6 are fixed to a base plate 13 and are then mounted on the cooler 7.

The base plate 13 and rear surfaces of the semiconductor modules 6 are joined by a joining material such as solder, silver, or grease having high electric conductivity and high thermal conductivity.

The base plate 13 is a plate mainly made of a metal having high electric conductivity and high thermal conductivity, such as aluminum or copper, and is fixed onto the cooler 7 with screws or the like.

The cooler 7 is a water jacket through which water for cooling the semiconductor modules 6 circulates, a heatsink including a heat dissipation fin, or the like.

Main terminals 10a drawn out from side surfaces of sealing materials 116 of the semiconductor modules 6 are connected to a busbar 8a. Main terminals 10b drawn out from the same side surfaces of the sealing materials 116 as the main terminals 10a are connected to a busbar 8b. The busbars 8a and 8b are thin conductor plates. An insulating material 8c is provided between the busbar 8a and the busbar 8b. The main terminals 10a and 10b may not necessarily be drawn out from the same side surface of the sealing materials 116.

The busbars 8a and 8b are bent and housed in a housing of a capacitor module 9 (not illustrated). The busbars 8a and 8b are connected to the capacitor module 9 by soldering or the like inside the housing.

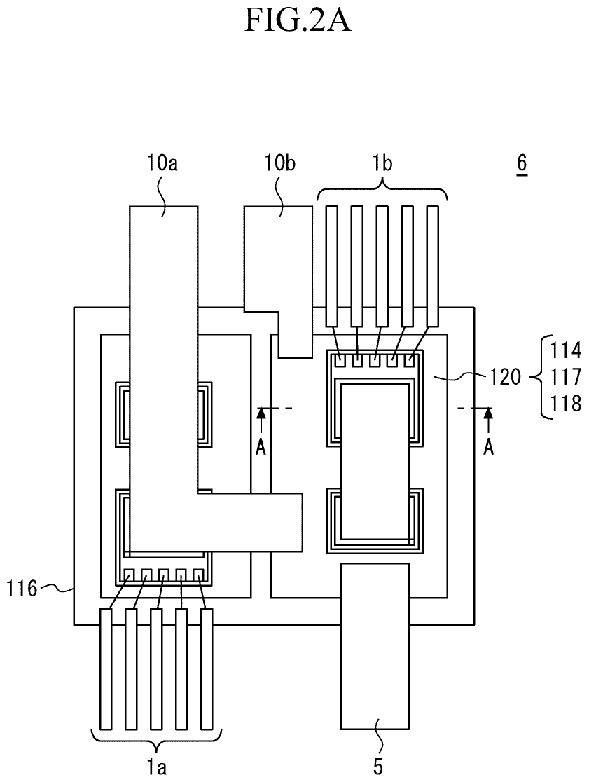

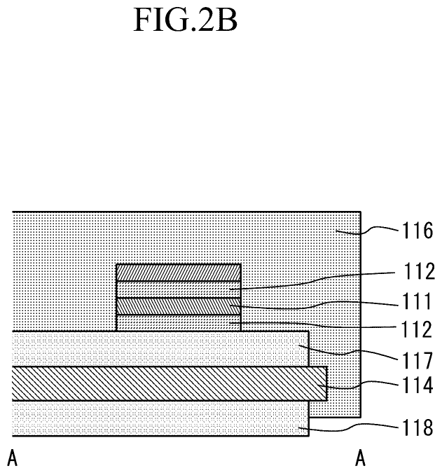

FIG. 2A is a top view illustrating one semiconductor module 6 according to the first embodiment of the present disclosure. FIG. 2B is a cross-sectional view taken along line A-A in FIG. 2A. Each semiconductor module 6 includes a substrate 120, a plurality of semiconductor devices 111 mounted on a circuit pattern 117 of the substrate 120, the main terminals 10a and 10b, control terminals 1a and 1b, and the sealing material 116.

Main electrodes (collector electrodes) on rear surfaces of the semiconductor devices 111 are joined with the circuit pattern 117 of the substrate 120 through joining materials 112. The joining materials 112 are sintered materials made of fine metal powder. Each of the semiconductor devices 111 is, for example, a diode, a metal-oxide-semiconductor field-effect transistor (MOSFET), an insulated-gate bipolar transistor (IGBT), or a reverse-conducting IGBT (RC-IGBT).

The substrate 120 includes an insulating layer 114, the circuit pattern 117 on an upper surface of the insulating layer 114, and a circuit pattern 118 on a rear surface of the insulating layer 114. When a metal material mainly containing copper, aluminum, or the like high in thermal conductivity is used for the circuit patterns 117 and 118, heat dissipation can be improved. The circuit patterns 117 and 118 are joined with the insulating layer 114 by brazing or the like. The circuit pattern 118 provided on the rear surface of the insulating layer 114 is exposed from a rear surface of the sealing material 116, and is joined with the base plate 13 through a joining material such as grease or solder.

The insulating layer 114 is provided between the circuit patterns 117 and 118. When a resin enduring deformation is used as the insulating layer 114, even if minute deformation occurs on a member due to heat cycle or the like, occurrence of cracks can be suppressed. When a material having high thermal conductivity is used as the insulating layer 114, it is possible to improve heat dissipation of the circuit patterns 117 and 118 through the insulating layer 114, and to suppress temperature rise of the semiconductor module 6. The material of the insulating layer 114 is not limited to the resin, and AlN, Al₂O₃, Si₃N₄, or the like may be used.

In a low-side device having a relatively low potential among the plurality of semiconductor devices 111, a main electrode (emitter electrode) on an upper surface is joined with the main terminal 10b through the joining material 112.

In the low-side device, the main electrode (collector electrode) on the rear surface is electrically connected to an output terminal 5. The output terminal 5 is joined with the circuit pattern 117 through a joining material. The output terminal 5 is connectable to an external apparatus such as a motor through an output busbar 4.

In a high-side device having a relatively high potential among the plurality of semiconductor devices 111, the main electrode (emitter electrode) on the upper surface is joined with the output terminal 5 through the joining material 112. In the high-side device, the main electrode (collector electrode) on the rear surface is electrically connected to the main terminal 10a. The main terminal 10a is joined with the circuit pattern 117 of the substrate 120 through a joining material.

A control electrode on the upper surface of each of the semiconductor devices 111 is joined with the control terminal 1a or the control terminal 1b through a joining material. The control terminals 1a and 1b may be joined with the circuit pattern 117 through joining materials.

The control terminal 1a and the control terminal 1b are drawn out from respective side surfaces opposed to each other, of the sealing material 116. In this example, the control terminal drawn out from the same side surface as the output terminal 5 is the control terminal 1a. The control terminal drawn out from the same side surface as the main terminals 10a and 10b is the control terminal 1b. The control terminals 1a and 1b are formed upward.

The main terminals 10a and 10b and the control terminals 1a and 1b are made of a conductive metal, for example, copper or a copper alloy.

The joining materials are provided between each of the semiconductor devices 111 and the circuit pattern 117, between each of the semiconductor devices 111 and each of the main terminals 10a and 10b, between each of the semiconductor devices 111 and each of the control terminals 1a and 1b, between the circuit pattern 117 and the main terminal 10a, and the like, and joins the corresponding members. The joining materials are preferably materials having high electric conductivity and high thermal conductivity, and solder, silver, or the like is used. Lead-free solder has a function as a buffer for reducing stress in addition to the above-described characteristics, and using the lead-free solder makes it possible to improve reliability of the semiconductor module 6. Alternatively, sintered silver can be used.

The substrate 120, the semiconductor devices 111, a part of the control terminals 1a and 1b, and a part of the main terminals 10a and 10b are sealed by the sealing material 116. The sealing material 116 is desirably a material that can improve reliability of the semiconductor module 6, and for example, a thermosetting epoxy resin material is used. As a sealing method, for example, a transfer molding method is used.

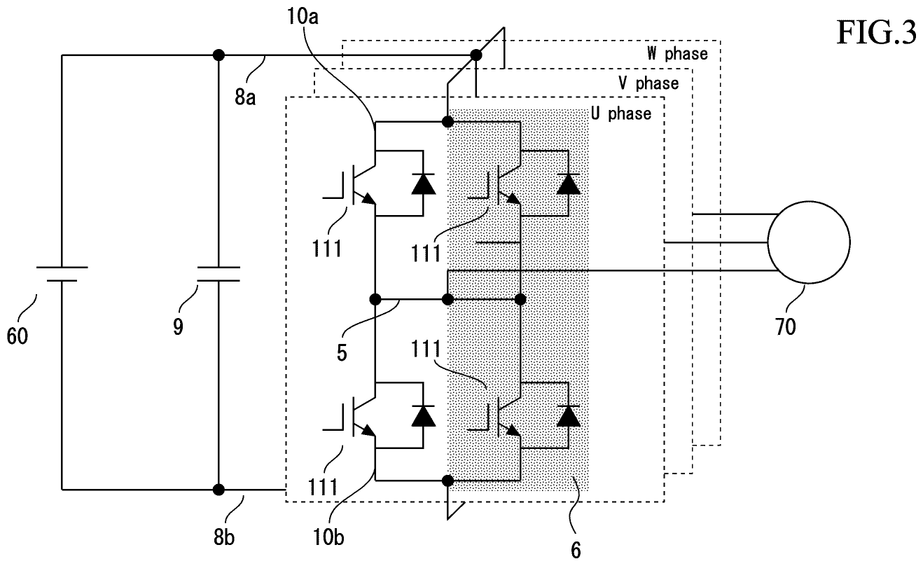

FIG. 3 is a circuit diagram of the semiconductor apparatus 100 according to the first embodiment of the present disclosure. A configuration example of a circuit suitable for a three-phase inverter apparatus is illustrated. In each phase, two semiconductor modules 6 are connected in parallel, and six semiconductor modules 6 are used in three phases as a whole.

Each of the semiconductor modules 6 is configured as a 2-in-1 circuit including two semiconductor devices 111 connected in series. A collector electrode of a high-side device having a relatively high potential out of the two semiconductor devices 111 included in the 2-in-1 circuit is connected to the main terminal 10a, and is connected to a positive electrode of the capacitor module 9 through the busbar 8a. On the other hand, an emitter electrode of a low-side device having a relatively low potential is connected to the main terminal 10b, and is connected to a negative electrode of the capacitor module 9 through the busbar 8b.

The capacitor module 9 is connected in parallel with an external power supply 60, and smooths a direct-current voltage from the external power supply 60. The number of capacitors included in the capacitor module 9 is not limited to one. In other words, the capacitor module 9 may be configured as a capacitor bank including a plurality of capacitors.

In each of the semiconductor modules 6, a middle point of the 2-in-1 circuit in which the two semiconductor devices 111 are connected in series is connected to the output terminal 5, and the output terminal 5 is connected to an external apparatus 70 such as a motor through the output busbar 4.

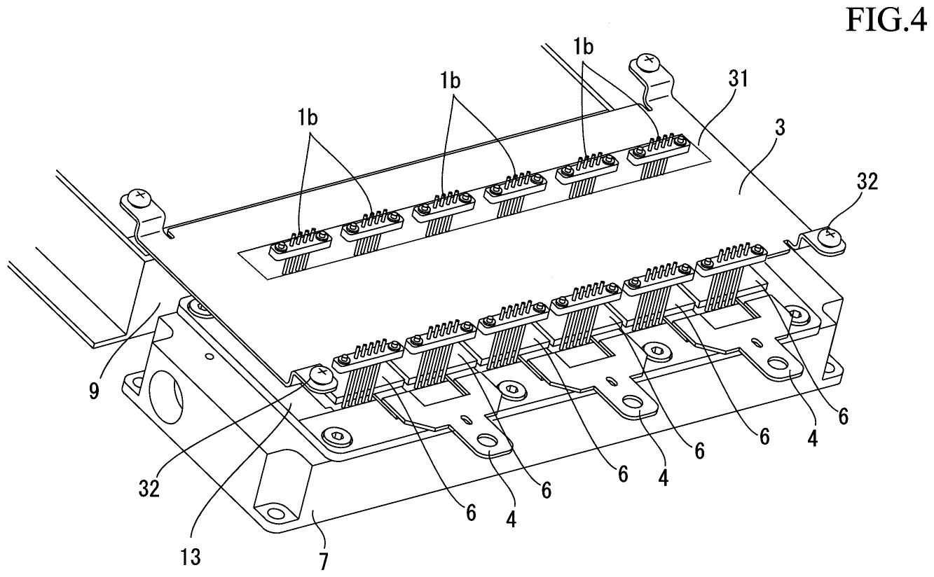

FIG. 4 is a perspective view of the plurality of semiconductor modules 6 and the shield plate 3 provided thereon according to the first embodiment of the present disclosure.

The busbars 8a and 8b and the insulating material 8c are bent and housed in the housing of the capacitor module 9. The busbar 8a and the busbar 8b are connected to different electrodes of the capacitor module 9 inside the housing. The busbars 8a and 8b and the insulating material 8c each have an exposed portion not covered with the housing of the capacitor module 9.

The shield plate 3 that covers over upper surfaces of the sealing materials 116 of the plurality of semiconductor modules 6 is provided. Although not illustrated for description, a control substrate 2 is essentially provided above the shield plate 3. In other words, the shield plate 3 is provided between the sealing materials 116 and the control substrate 2, and covers the upper surfaces of the sealing materials 116 facing the control substrate 2. The upper surfaces of the sealing materials 116 facing the control substrate 2 are covered with the shield plate 3, which makes it possible to suppress influence of radiation noise derived from the semiconductor devices 111, on the control substrate 2. The shield plate 3 is made of a material shielding against the radiation noise, for example, a metal such as aluminum or copper, graphite, or a material containing a magnetic substance. The shield plate 3 is fixed to the control substrate 2 through screw holes 32.

The shield plate 3 is extended from the upper surfaces of the sealing materials 116 of the respective semiconductor modules 6 so as to cover a part or all of the exposed portions of the busbars 8a and 8b not covered with the housing of the capacitor module 9. Accordingly, it is possible to prevent radiation noise derived from the exposed portions of the busbars 8a and 8b and the main terminals 10a and 10b drawn out to the outside of the sealing materials 116, from affecting the control substrate 2.

FIG. 5 is a top view of FIG. 4. The shield plate 3 includes an opening 31 through which the control terminals 1b formed upward are made to pass.

The control terminals 1b of all of the semiconductor modules 6 may not be made to collectively pass through one opening 31. In other words, the control terminals 1b of the respective semiconductor modules 6 may be made to individually pass through the openings 31 provided for the respective semiconductor modules 6. As compared with the case where the control terminals 1b are made to collectively pass through one opening 31, areas of the openings 31 can be reduced. This makes it possible to enhance the shielding effect of the shield plate 3.

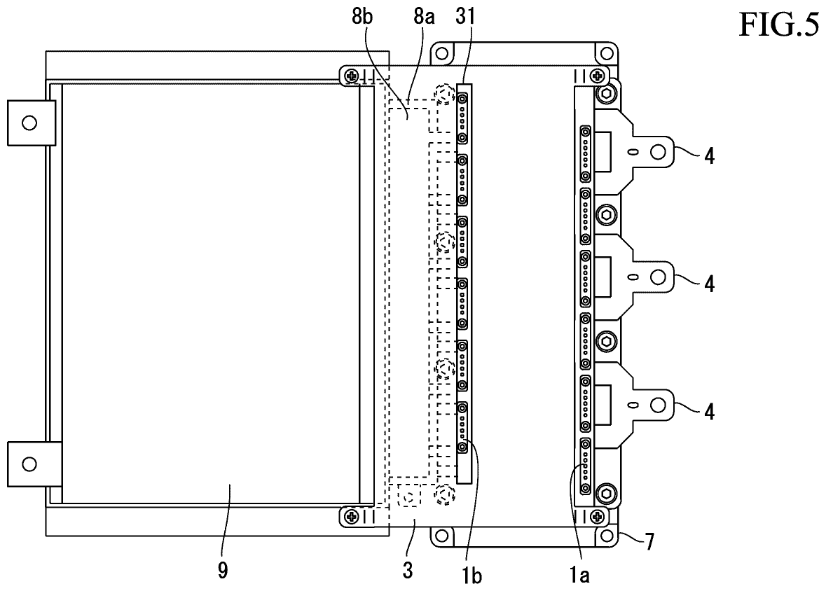

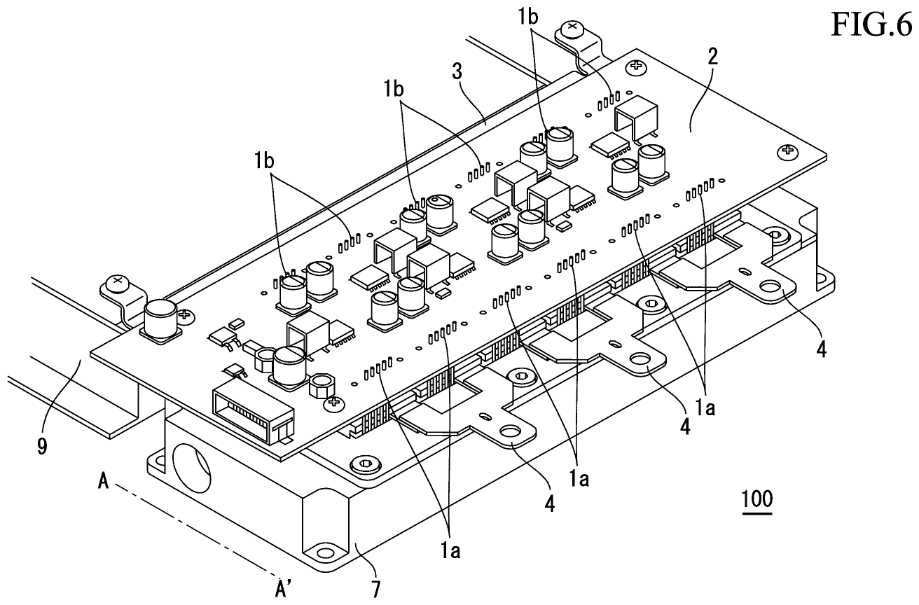

FIG. 6 is a perspective view illustrating the semiconductor apparatus 100 according to the first embodiment of the present disclosure.

The control substrate 2 is provided above the shield plate 3. The plurality of control terminals 1a and 1b are made to pass through through holes of the control substrate 2.

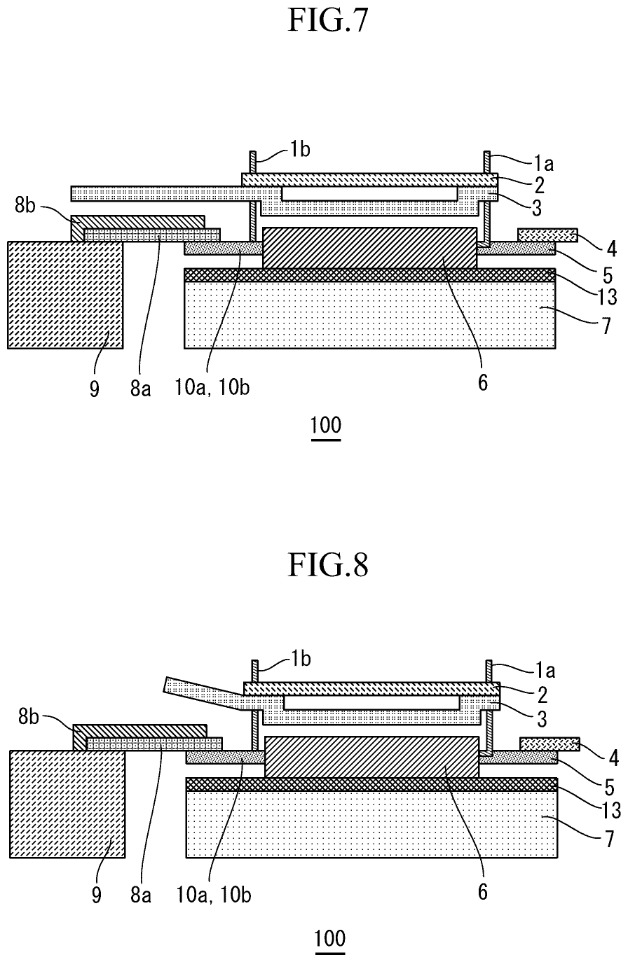

FIG. 7 is a side view taken along line A-A′ in FIG. 6. In the drawing, illustration of the insulating material 8c is omitted. It is obvious that the exposed portions of the busbars 8a and 8b are covered with the shield plate 3.

The shield plate 3 is fixed to the control substrate 2. The shield plate 3 and the control substrate 2 are electrically insulated from each other. A method of fixing the shield plate 3 is not limited thereto. The shield plate 3 may be fixed to a housing that houses the semiconductor modules 6 or the like, or may be fixed by other methods.

As described above, the shield plate 3 according to the present embodiment is provided between the sealing materials 116 and the control substrate 2, and covers the upper surfaces of the sealing materials 116 facing the control substrate 2. The shield plate 3 is extended so as to cover a part or all of the exposed portions of the busbars 8a and 8b not covered with the housing of the capacitor module 9. Accordingly, it is possible to prevent the radiation noise generated outside the sealing materials 116 sealing the semiconductor devices 111, from affecting the control substrate 2.

### [First Modification of First Embodiment]

FIG. 8 illustrates a modification of the semiconductor apparatus 100 according to the first embodiment of the present disclosure. FIG. 8 illustrates the same side surface as in FIG. 7. The portion of the shield plate 3 extended to cover the exposed portions of the busbars 8a and 8b may be bent to be inclined toward the control substrate 2. Also in this case, effects similar to the above-described effects are achievable.

### [Second Modification of First Embodiment]

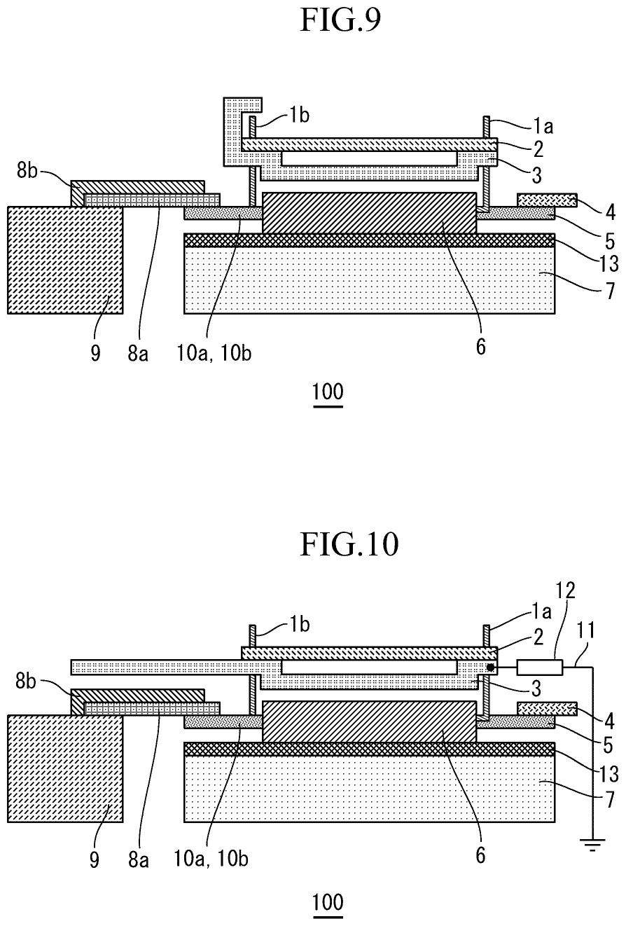

FIG. 9 illustrates another modification of the semiconductor apparatus 100 according to the first embodiment of the present disclosure. FIG. 9 also illustrates the same side surface as in FIG. 7. The shield plate 3 may be bent to cover a side surface of the control substrate 2 near the exposed portions of the busbars 8a and 8b. In addition, the bent portion of the shield plate 3 may be further bent to extend over an upper surface of the control substrate 2 at upper parts of the control terminals 1b protruding from the control substrate 2. This makes it possible to prevent the radiation noise generated outside the sealing materials 116, from being routed to the upper surface of the control substrate 2. In the drawing, the shield plate 3 is bent by 90 degrees, but a bending angle is not limited to 90 degrees.

### [Third Modification of First Embodiment]

The portion of the shield plate 3 extended to cover the exposed portions of the busbars 8a and 8b may be further extended to cover a part or all of the housing of the capacitor module 9. As a result, it is possible to shield against radiation noise derived from the capacitor module 9. This is true of all embodiments described below.

### [Fourth Modification of First Embodiment]

Each of the semiconductor modules 6 may not include the plurality of semiconductor devices 111, and may include one semiconductor device 111. In this case, the collector electrode of the one semiconductor device 111 is connected to the main terminal 10a, and is connected to one electrode of the capacitor module 9 through the busbar 8a. At the same time, the emitter electrode is connected to the main terminal 10b, and is connected to the other electrode of the capacitor module 9 through the busbar 8b. Also in this case, effects similar to the above-described effects are achievable. Further, the plurality of semiconductor modules 6 may not be mounted on the semiconductor apparatus 100, and one semiconductor module 6 may be mounted on the semiconductor apparatus 100. This is true of all embodiments described below.

### [Fifth Modification of First Embodiment]

The semiconductor devices 111 are not limited to the semiconductor devices made of silicon, and may be made of a wide bandgap semiconductor having a bandgap greater than a bandgap of silicon. Examples of the wide bandgap semiconductor include silicon carbide, a gallium nitride material, and diamond. The semiconductor devices 111 made of such a wide bandgap semiconductor can be downsized because of high withstand voltage and high allowable current density. Using the downsized semiconductor devices 111 makes it possible to downsize and highly integrate the semiconductor apparatus 100 in which the semiconductor devices 111 are incorporated. Further, since the semiconductor devices 111 have high heat resistance, a heat dissipation fin of a heatsink can be downsized, and a water-cooling unit can be substituted with an air-cooling unit. This makes it possible to further downsize the semiconductor apparatus 100. The semiconductor devices 111 are low in power loss and high in efficiency. Thus, the semiconductor apparatus 100 can be increased in efficiency. Note that all of the semiconductor devices 111 are desirably made of the wide bandgap semiconductor; however, some of the semiconductor devices 111 may be made of the wide bandgap semiconductor, and effects described in the present embodiment are achievable. This is true of all embodiments described below.

### Second Embodiment

In the following, changes from the first embodiment are described.

FIG. 10 is a side view illustrating the semiconductor apparatus 100 according to a second embodiment of the present disclosure. FIG. 10 illustrates the same side surface as in FIG. 7 according to the first embodiment. In the present embodiment, the shield plate 3 is grounded by a ground wire 11. The ground wire 11 is provided with a resistor 12. This makes it possible to release induced electromotive force generated by polarization of the shield plate 3 by the radiation noise, to the outside of the semiconductor apparatus 100. In addition, the ground wire 11 is provided with the resistor 12, which makes it possible to prevent the radiation noise from flowing reversely.

### Third Embodiment

FIG. 11 is a side view illustrating the semiconductor apparatus 100 according to a third embodiment of the present disclosure. FIG. 11 also illustrates the same side surface as in FIG. 7 according to the first embodiment. In the present embodiment, the portion of the shield plate 3 extended to cover the exposed portions of the main terminals 10a and 10b is bent in a wave shape. This makes it possible to disperse a traveling direction of the radiation noise absorbed into the shield plate 3. When the radiation noise is applied from the shield plate 3 to the control substrate 2 by reradiation or the like, influence thereof can be reduced.

### Fourth Embodiment

In a fourth embodiment, the semiconductor apparatus 100 according to any of the above-described first to third embodiments is applied to a power conversion apparatus of a three-phase inverter. The present disclosure is not limited to a specific power conversion apparatus, and is applicable to, for example, an inverter apparatus, a converter apparatus, a servo amplifier, and a power supply unit.

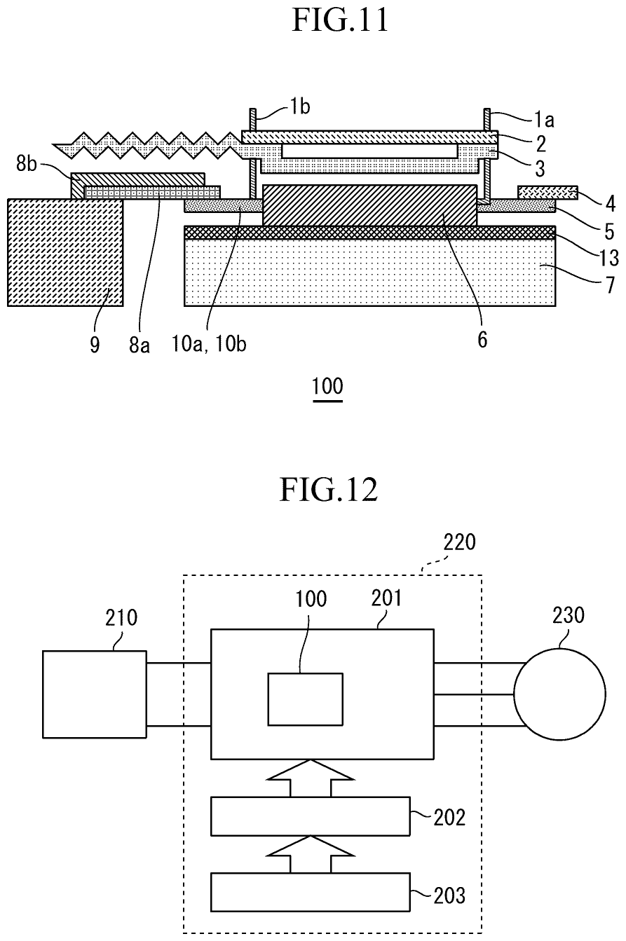

FIG. 12 is a block diagram illustrating a configuration of a power conversion system according to the fourth embodiment of the present disclosure. The power conversion apparatus 220 includes a power supply 210, a power conversion apparatus 220, and a load 230. The power supply 210 is a direct-current power supply, and supplies direct-current power to the power conversion apparatus 220. The power supply 210 can be configured by various components such as a direct-current system, a solar cell, and a storage battery, or may be configured by a rectifier circuit or an AC/DC converter connected to an alternating-current system. Alternatively, the power supply 210 may be configured by a DC/DC converter that converts direct-current power output from a direct-current system into predetermined power.

The power conversion apparatus 220 is a three-phase inverter connected between the power supply 210 and the load 230, converts the direct-current power supplied from the power supply 210 into alternating-current power, and supplies the alternating-current power to the load 230. The power conversion apparatus 220 includes a main conversion circuit 201 that converts the direct-current power into alternating-current power and outputs the alternating-current power, a drive circuit 202 that outputs drive signals for driving switching devices of the main conversion circuit 201, and a control circuit 203 that outputs a control signal for controlling the drive circuit 202, to the drive circuit 202.

The load 230 is a three-phase electric motor driven by the alternating-current power supplied from the power conversion apparatus 220. The load 230 is not limited to a specific application, is an electric motor mounted on various kinds of electric machines, and is used as an electric motor for, for example, a hybrid vehicle, an electric vehicle, a railway vehicle, an elevator, or an air conditioner.

The power conversion apparatus 220 is described in detail below. The main conversion circuit 201 includes the switching devices and freewheel diodes (not illustrated). When the switching devices are switched, the main conversion circuit 201 converts the direct-current power supplied from the power supply 210 into alternating-current power, and supplies the alternating-current power to the load 230. The main conversion circuit 201 may have various types of specific circuit configurations. The main conversion circuit 201 according to the present embodiment is a two-level three-phase full-bridge circuit that includes six switching devices and six freewheel diodes connected in antiparallel with the respective switching devices.

Each of the switching devices and the freewheel diodes of the main conversion circuit 201 is configured by the semiconductor apparatus 100 according to the above-described first embodiment. Each two of the six switching devices are connected in series and configure upper and lower arms, and each pair of upper and lower arms configures each phase (U phase, V phase, or W phase) of the full-bridge circuit. Output terminals of respective pairs of upper and lower arms, namely, three output terminals of the main conversion circuit 201 are connected to the load 230.

The drive circuit 202 may be incorporated in the semiconductor apparatus 100, or may be provided separately from the semiconductor apparatus 100. The drive circuit 202 generates the drive signals for driving the switching devices of the main conversion circuit 201, and supplies the drive signals to control electrodes of the switching devices of the main conversion circuit 201. More specifically, in response to the control signal from the control circuit 203 described below, the drive circuit 202 outputs the drive signal for turning on each of the switching devices and the drive signal for turning off each of the switching devices, to the control electrode of each of the switching devices. To maintain each of the switching devices in an on state, the drive signal is a voltage signal (ON signal) having a voltage greater than or equal to a threshold voltage of the switching device. To maintain each of the switching devices in an off state, the drive signal is a voltage signal (OFF signal) having a voltage less than the threshold voltage of the switching device.

The control circuit 203 controls the switching devices of the main conversion circuit 201 to supply desired power to the load 230. More specifically, based on power to be supplied to the load 230, the control circuit 203 calculates a period (ON period) when each of the switching devices of the main conversion circuit 201 is to be turned on. For example, the main con version circuit 201 can be controlled by PWM control for modulating the ON period of each of the switching devices based on the voltage to be output. The control circuit 203 outputs the control signal to the drive circuit 202 such that, at each time point, the ON signal is output to each of the switching devices to be turned on, and the OFF signal is output to each of the switching devices to be turned off. In response to the control signal, the drive circuit 202 outputs the ON signal or the OFF signal as the drive signal to the control electrode of each of the switching devices.

In the power conversion apparatus according to the present embodiment, the semiconductor apparatus 100 according to the first embodiment is applied as each of the switching devices of the main conversion circuit 201. Therefore, it is possible to provide the power conversion apparatus including the semiconductor apparatus that can prevent radiation noise generated outside the sealing materials 116 sealing the semiconductor devices 111, from affecting the control substrate 2.

In the present embodiment, the example in which the present disclosure is applied to the two-level three-phase inverter is described; however, the present disclosure is not limited thereto, and is applicable to various power conversion apparatuses. In the present embodiment, the power conversion apparatus is the two-level power conversion apparatus, but may be a three-level or multi-level power conversion apparatus. In a case where power is supplied to a single-phase load, the present disclosure may be applied to a single-phase inverter. In a case where power is supplied to a direct-current load or the like, the present disclosure can be applied to a DC/DC converter or an AC/DC converter.

The power conversion apparatus to which the present disclosure is applied is not limited to the above-described case where the load is the electric motor, can be used as a power supply apparatus for, for example, an electric discharge machine, a laser machine, an induction heating cooker, or a non-contact device power feeding system, or can be used as a power conditioner for a photovoltaic power generation system, a power storage system, and the like.

As described above, the shield plate 3 according to the present disclosure is provided between the sealing material 116 and the control substrate 2, and covers the upper surface of the sealing material 116 facing the control substrate 2. The shield plate 3 is extended to cover a part or all of the exposed portions of the busbars 8a, 8b not covered with the housing of the capacitor module 9. Alternatively, the shield plate 3 is bent to cover the side surface of the control substrate 2 near the exposed portions. Accordingly, it is possible to prevent radiation noise generated outside the sealing material 116 sealing the semiconductor device 111, from affecting the control substrate 2.

The present disclosure is not limited to the above-described embodiments, and can be variously modified without departing from the spirit thereof in implementation. Further, the embodiments and the modifications may be appropriately implemented in combination. In this case, combined effects are achievable.

[Correspondence with Terms Used in Claims]

The collector electrode is an example of a first main electrode. The emitter electrode is an example of a second main electrode. The main terminal 10a is an example of a first main terminal. The main terminal 10b is an example of a second main terminal. The busbar 8a is an example of a first busbar. The busbar 8b is an example of a second busbar. The positive electrode is an example of a first electrode of the capacitor module 9. The negative electrode is an example of a second electrode of the capacitor module 9.

Hereinafter, various aspects of the present disclosure will be collectively described as appendixes.

### APPENDIX 1

A semiconductor apparatus, including:
a semiconductor device including a control electrode, a first main electrode, and a second main electrode;
a control terminal connected to the control electrode;
first and second main terminals respectively connected to the first and second main electrodes;
a sealing material configured to seal the semiconductor device, a part of the control terminal, and a part of the first and second main terminals;
a capacitor module including a housing and first and second electrodes drawn out from the housing;
a first busbar connected to the first electrode, and connected to the first main terminal outside the sealing material;
a second busbar connected to the second electrode, and connected to the second main terminal outside the sealing material;
a control substrate disposed to face an upper surface of the sealing material, and connected to the control terminal; and
a shield plate disposed between the sealing material and the control substrate, and configured to shield against radiation, in which
the shield plate is extended to cover exposed portions of the first and second busbars not covered with the housing, or is bent to cover a side surface of the control substrate near the exposed portions.

### APPENDIX 2

The semiconductor apparatus according to appendix 1, in which a portion of the shield plate extended to cover the exposed portions or a portion of the shield plate bent to cover the side surface has a wave shape.

### APPENDIX 3

The semiconductor apparatus according to appendix 1 or 2, in which a portion of the shield plate extended to cover the exposed portions is further extended to cover at least a part of the housing of the capacitor module.

### APPENDIX 4

The semiconductor apparatus according to appendix 1 or 2, in which a portion of the shield plate extended to cover the exposed portions is bent to be inclined toward the control substrate.

### APPENDIX 5

The semiconductor apparatus according to appendix 1 or 2, in which a portion of the shield plate bent to cover the side surface of the control substrate near the exposed portions is further bent to extend over an upper surface of the control substrate.

### APPENDIX 6

The semiconductor apparatus according to any one of appendixes 1 through 5, in which the shield plate includes an opening through which the control terminal is made to pass.

### APPENDIX 7

The semiconductor apparatus according to any one of appendixes 1 through 6, in which the shield plate is electrically grounded.

### APPENDIX 8

The semiconductor apparatus according to any one of appendixes 1 through 7, in which the semiconductor device is made of a wide bandgap semiconductor.

### APPENDIX 9

A power conversion apparatus, including:
a main conversion circuit including the semiconductor apparatus according to any one of appendixes 1 through 8, and configured to convert input power and to output converted power; and
a control circuit configured to output a control signal for controlling the main conversion circuit, to the main conversion circuit.

Obviously many modifications and variations of the present disclosure are possible in the light of the above teachings. It is therefore to be understood that within the scope of the appended claims the invention may be practiced otherwise than as specifically described.

The entire disclosure of Japanese Patent Application No. 2024-80113, filed on May 16, 2024 including specification, claims, drawings and summary, on which the convention priority of the present application is based, is incorporated herein by reference in its entirety.

1. A semiconductor apparatus, comprising:
a semiconductor device including a control electrode, a first main electrode, and a second main electrode;
a control terminal connected to the control electrode;
first and second main terminals respectively connected to the first and second main electrodes;
a sealing material configured to seal the semiconductor device, a part of the control terminal, and a part of the first and second main terminals;
a capacitor module including a housing and first and second electrodes drawn out from the housing;
a first busbar connected to the first electrode, and connected to the first main terminal outside the sealing material;
a second busbar connected to the second electrode, and connected to the second main terminal outside the sealing material;
a control substrate disposed to face an upper surface of the sealing material, and connected to the control terminal; and
a shield plate disposed between the sealing material and the control substrate, and configured to shield against radiation, wherein
the shield plate is extended to cover a part or all of exposed portions of the first and second busbars not covered with the housing, or is bent to cover a side surface of the control substrate near the exposed portions.

2. The semiconductor apparatus according to claim 1, wherein a portion of the shield plate extended to cover the exposed portions or a portion of the shield plate bent to cover the side surface has a wave shape.

3. The semiconductor apparatus according to claim 1, wherein a portion of the shield plate extended to cover the exposed portions is further extended to cover at least a part of the housing of the capacitor module.

4. The semiconductor apparatus according to claim 2, wherein a portion of the shield plate extended to cover the exposed portions is further extended to cover at least a part of the housing of the capacitor module.

5. The semiconductor apparatus according to claim 1, wherein a portion of the shield plate extended to cover the exposed portions is bent to be inclined toward the control substrate.

6. The semiconductor apparatus according to claim 2, wherein a portion of the shield plate extended to cover the exposed portions is bent to be inclined toward the control substrate.

7. The semiconductor apparatus according to claim 1, wherein a portion of the shield plate bent to cover the side surface of the control substrate near the exposed portions is further bent to extend over an upper surface of the control substrate.

8. The semiconductor apparatus according to claim 2, wherein a portion of the shield plate bent to cover the side surface of the control substrate near the exposed portions is further bent to extend over an upper surface of the control substrate.

9. The semiconductor apparatus according to claim 1, wherein the shield plate includes an opening through which the control terminal is made to pass.

10. The semiconductor apparatus according to claim 2, wherein the shield plate includes an opening through which the control terminal is made to pass.

11. The semiconductor apparatus according to claim 1, wherein the shield plate is electrically grounded.

12. The semiconductor apparatus according to claim 2, wherein the shield plate is electrically grounded.

13. The semiconductor apparatus according to claim 1, wherein the semiconductor device is made of a wide bandgap semiconductor.

14. The semiconductor apparatus according to claim 2, wherein the semiconductor device is made of a wide bandgap semiconductor.

15. A power conversion apparatus, comprising:
a main conversion circuit including the semiconductor apparatus according to claim 1, and configured to convert input power and to output converted power; and
a control circuit configured to output a control signal for controlling the main conversion circuit, to the main conversion circuit.

16. A power conversion apparatus, comprising:
a main conversion circuit including the semiconductor apparatus according to claim 2, and configured to convert input power and to output converted power; and
a control circuit configured to output a control signal for controlling the main conversion circuit, to the main conversion circuit.
